(19) United States
(12) Patent Application Publication
(10) Pub. No.: US 2024/0271266 A1
(43) Pub. Date: Aug. 15, 2024

(54) Air Gap Formation by Physical Vapor Deposition

(71) Applicant: Applied Materials, Inc., Santa Clara, CA (US)

(72) Inventors: Chengyu LIU, San Jose, CA (US); Xianmin TANG, San Jose, CA (US)

(21) Appl. No.: 18/108,325

(22) Filed: Feb. 10, 2023

(51) Int. Cl. C23C 14/00; C23C 14/10; C23C 14/34; H01J 37/317

(52) U.S. Cl. CPC C23C 14/0036; C23C 14/10; C23C 14/345; C23C 14/3485; C23C 14/3492; H01J 37/3178; H01J 2237/2001

(57) ABSTRACT

Methods for forming an airgap within a structure of a substrate, comprising anisotropically depositing a layer of SiO₂ on a top surface of the substrate to form a cap over the structure and the airgap disposed between the cap and a bottom surface of the structure via reactive negative ion sputtering of a silicon (Si) target in a presence of diatomic oxygen in an inert carrier gas, wherein the target is pulsed at a voltage of less than or equal to about −200 V at a pulse rate of greater than about 10 KHz. A substrate having an airgap is also disclosed.

### FIELD

Embodiments of the present disclosure generally relate to processing of a semiconductor substrate or device, and in particular, to forming an airgap within a structure disposed in a substrate.

### BACKGROUND

The inventors have observed that the scaling down of DRAM structures especially beyond 20 nm nodes results in bitline sensing margin becoming problematic due to the increasing ratio of parasitic bitline capacitance (Cb) to cell capacitance (Cs). The inventors have noticed that air gap structures may be utilized to decrease Cb in low Cs applications. However, the inventors have also observed that processes for forming an air gap do not provide adequate results.

Thus, the inventors have provided improved techniques for forming air gaps in structures.

### SUMMARY

In embodiments, a method to form an airgap within a structure of a substrate comprises anisotropically deposit a layer of SiO₂ on a top surface of the substrate to form a cap over the structure and the airgap disposed between the cap and a bottom surface of the structure via reactive negative ion sputtering of a silicon (Si) target in a presence of diatomic oxygen in an inert carrier gas, wherein the target is pulsed at a voltage of less than or equal to about −200 V at a pulse rate of greater than about 10 KHz.

In embodiments, a substrate comprises a structure disposed within the substrate having a structure width of less than or equal to about 20 nm, and a structure depth of greater than or equal to about 60 nm; and a layer of SiO₂ disposed over a top surface of the substrate forming a cap over the structure with an airgap disposed between the cap and a bottom surface of the structure; wherein a distance from a top of the airgap to a point coplanar with a top surface of the substrate is greater than or equal to about 25 nm; wherein a maximum width of the airgap formed is greater than or equal to about 40% of the structure width; and wherein a length of the airgap is greater than or equal to about 25 nm less than the structure depth.

In embodiments, a non-transitory computer readable medium is provided, having instructions stored thereon which, when executed, causes a processing chamber to perform any of the methods described herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flowchart depicting a method to form an airgap within a structure of a substrate according to an embodiment.

FIG. 2 is a flowchart depicting a method to form an airgap within a structure of a substrate according to an embodiment.

FIG. 3 depicts a reaction chamber suitable for use according to embodiments disclosed herein.

FIG. 4a depicts a structure disposed in a substrate having a portion of a layer of SiO₂ disposed over a portion of the top surface, but which does not form a cap over the structure according to embodiments disclosed herein.

FIG. 4b depicts a structure disposed in a substrate having a layer of SiO₂ disposed over the top surface forming a cap over the structure with an airgap disposed within the structure according to embodiments disclosed herein.

FIG. 4c depicts a structure disposed in a substrate having a layer of SiO₂ disposed over the top surface forming a cap over the structure with an airgap disposed within the structure according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a method to form an airgap within a structure of a substrate are provided herein. In embodiments, the method comprises anisotropically depositing a layer of SiO₂ or other dielectric material having a dielectric constant less than or equal to about that of SiO₂ on a top surface of the substrate to form a cap over the structure and the airgap disposed between the cap and a bottom surface of the structure via reactive negative ion sputtering of a silicon (Si) target in a presence of diatomic oxygen in an inert carrier gas, wherein the target is pulsed at a voltage of less than or equal to about −200 V at a pulse rate of greater than about 10 KHz. In embodiments, the target is pulsed at a voltage of about −300 V to about −500 V at a pulse rate from about 10 kHz to about 1000 KHz. In embodiments, the method further comprises applying an RF bias to the substrate of less than or equal to about 500 W. In some embodiments, the RF bias is applied at a frequency from about 2 MHz to about 20 MHz.

In embodiments, a weight-to-weight ratio (weight:weight) of diatomic oxygen to the inert carrier gas is greater than or equal to about 1:1. In embodiments, the inert carrier gas comprises argon, and the weight-to-weight ratio of diatomic oxygen to argon is greater than or equal to about 10:1.

In embodiments, the substrate is maintained at a temperature from about 200° C. to about 500° C.

In embodiments, the structure disposed in the substrate has a structure width of less than or equal to about 20 nm, and a structure depth of greater than or equal to about 60 nm, determined from a point coplanar with the top surface of the substrate to a bottom surface of the substrate.

In embodiments, a maximum width of the airgap formed within the structure is greater than or equal to about 40% of a structure width. Stated another way, the maximum width of the airgap formed within the structure is from the structure width to about 40% of the structure width. In embodiments, the maximum width of the airgap formed within the structure is greater than 90% of the structure width.

In embodiments, a distance from a top of the airgap to a point coplanar with the top surface of the substrate is greater than or equal to about 25 nm. In embodiments, the distance from the top of the airgap to the point coplanar with the top surface of the structure is from about 30 nm to about 40 nm. In embodiments, a length of the airgap is from about 25 nm less than a structure depth to about 45 nm less than the structure depth.

In embodiments, the anisotropically depositing the layer of SiO₂ on a top surface of the substrate to form the cap over the structure and the airgap disposed between the cap and the bottom surface of the structure comprises depositing a first layer of SiO₂ on the top surface of the substrate at a first deposition rate, followed by depositing a second layer of SiO₂ on the first layer and on portions of the top surface of the substrate not covered by the first layer at a second deposition rate to form the cap over the structure, wherein the second deposition rate is greater than the first deposition rate.

In embodiments, the first layer of SiO₂ is deposited while the target is pulsed at a first voltage, and the second layer is deposited while the target is pulsed at a second voltage which is less than the first voltage. In embodiments, a first weight-to-weight ratio of diatomic oxygen to the inert carrier gas of the first deposition rate is less than a second weight-to-weight ratio of diatomic oxygen to the inert carrier gas of the second deposition rate. In embodiments, an RF bias is applied to the substrate during the first deposition rate at a first power, and the RF bias applied to the substrate during the second deposition rate is at a second power which is less than the first power.

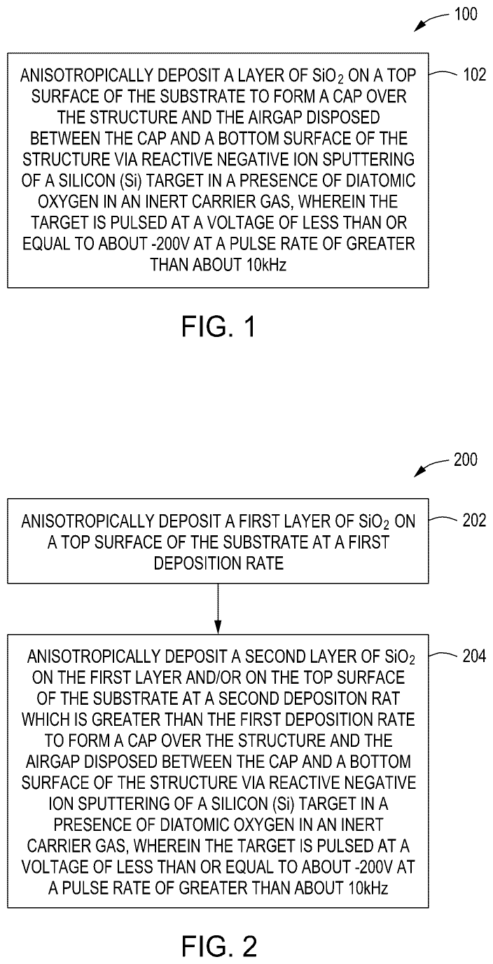

FIG. 1 is a flowchart of an example method 100 to form an airgap within a structure of a substrate.

As shown in FIG. 1, the method 100 may include anisotropically depositing a layer of SiO₂ on a top surface of the substrate to form a cap over the structure and the airgap disposed between the cap and a bottom surface of the structure via reactive negative ion sputtering of a silicon (Si) target in a presence of diatomic oxygen in an inert carrier gas, where the target is pulsed at a voltage of less than or equal to about −200 V at a pulse rate of greater than about 10 kHz (block 102).

The method 100 may include additional embodiments, such as any single embodiment or any combination of embodiments described below and/or in connection with one or more other processes described elsewhere herein. In embodiments, the target is pulsed at a voltage of about −300 V to about −500 V at a pulse rate from about 10 KHz to about 1000 kHz. In some embodiments, the voltage is less than or equal to about −200 V, or less than or equal to about −250 V, or less than or equal to about −300 V, or less than or equal to about −350 V, or less than or equal to about −400 V, or less than or equal to about −450 V, or less than or equal to about −500 V.

In embodiments, the method 100 may include applying an RF bias to the substrate, which in embodiments may be at a power of less than or equal to about 500 W and the RF bias may be applied at a frequency from about 2 MHz to about 20 MHz. In embodiments, an RF bias applied to the substrate is less than or equal to about 500 W, or less than or equal to about 450 W, or less than or equal to about 400 W, or less than or equal to about 350 W, or less than or equal to about 300 W, or less than or equal to about 250 W, or less than or equal to about 200 W, or less than or equal to about 150 W, or less than or equal to about 100 W, or less than or equal to about 50 W, or less than or equal to about 10 W. In embodiments, the lower limit of the RF bias applied to the substrate is greater than or equal to about 1 W.

In some embodiments of the method 100, alone or in combination with one or more other embodiments, a weight-to-weight ratio of diatomic oxygen to the inert carrier gas is greater than or equal to about 1:1. In embodiments, the inert carrier gas comprises argon. In some embodiments, the inter carrier gas consists essentially of or consists of argon. In embodiments of the method 100, the weight-to-weight ratio of diatomic oxygen to the inert carrier gas is greater than or equal to about 10:1, or greater than or equal to about 100:1, greater than or equal to about 1000:1. In some embodiments, the weight-to-weight ratio of diatomic oxygen to argon is greater than or equal to about 10:1, or greater than or equal to about 100:1, greater than or equal to about 1000:1.

In some embodiments of the method 100, the substrate is maintained at a temperature of greater than or equal to about 200° C., or greater than or equal to about 300° C., or greater than or equal to about 400° C., and less than or equal to about 500° C.

FIG. 2 is a flowchart of an example method 200, a method to form an airgap within a structure of a substrate. In some embodiments, one or more process blocks of FIG. 2 may be performed by a device.

As shown in FIG. 2, method 200 may include anisotropically depositing a first layer of SiO₂ on a top surface of the substrate at a first deposition rate (block 202), which in embodiments may only partially cover the top surface of the substrate, e.g., a seed layer, which is followed by depositing a second layer of SiO₂ on the top surface of the substrate at a second deposition rate which is greater than the first deposition rate to form a cap over the structure and the airgap disposed between the cap and a bottom surface of the structure via reactive negative ion sputtering of a silicon (Si) target in a presence of diatomic oxygen in an inert carrier gas, where the target is pulsed at a voltage of less than or equal to about −200 V at a pulse rate of greater than about 10 kHz (block 204).

Method 200 may include additional embodiments, such as any single embodiment or any combination of embodiments described in connection with method 100, and/or in connection with one or more other processes described elsewhere herein. In an embodiment, the first voltage of the first deposition rate is higher than a second voltage of the second deposition rate. In embodiments, the first voltage of the first deposition rate is from about −200 V to greater than or equal to about −250 V, or greater than or equal to about −300 V, and the second voltage of the second deposition rate is less than or equal to about −300 V, or less than or equal to about −350 V, or less than or equal to about −400 V, or less than or equal to about −450 V, or less than or equal to about −500 V.

In embodiments, a first weight-to-weight ratio of diatomic oxygen to the inert carrier gas of the first deposition rate is less than a second weight-to-weight ratio of diatomic oxygen to the inert carrier gas of the second deposition rate. In embodiments, a first weight-to-weight ratio of diatomic oxygen to the inert carrier gas of the first deposition rate is greater than or equal to about 1:1, or greater than or equal to about 10:1, or greater than or equal to about 100:1, and a second-weight-to weight ratio of diatomic oxygen to the inert carrier gas of the second deposition rate is greater than or equal to about 10:1, or greater than or equal to about 100:1, or greater than or equal to about 500:1, or greater than or equal to about 1000:1.

In embodiments, an RF bias is applied to the substrate during the first deposition rate at a first power of less than or equal to about 500 W, or less than or equal to about 450 W, or less than or equal to about 400 W, or less than or equal to about 350 W, and the RF bias is applied to the substrate during the second deposition rate at a second power of less than or equal to about 300 W, or less than or equal to about 250 W, or less than or equal to about 200 W, or less than or equal to about 150 W, or less than or equal to about 100 W, or less than or equal to about 50 W, or less than or equal to about 10 W. In embodiments, the lower limit of the RF bias applied to the substrate is greater than or equal to about 1 W.

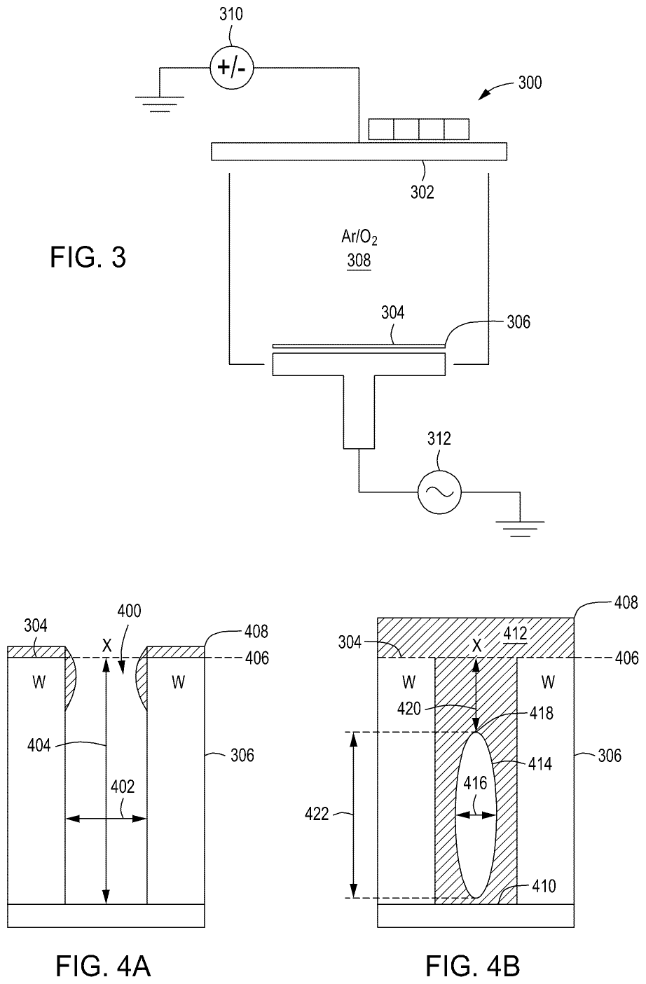

FIG. 3 schematically depicts a reaction chamber 300 according to embodiments disclosed herein, wherein a silicon (Si) target 302 is utilized to anisotropically deposit a layer of silicon dioxide (SiO₂) on a top surface 304 of a substrate 306 via reactive negative ion sputtering of the Si target 302 in a presence of diatomic oxygen in an inert carrier gas (depicted in a processing volume 308 of the reaction chamber 300), e.g., Ar/O₂. The Si target 302 is coupled to a DC power source 310 and pulsed at a voltage of less than or equal to about −200 V at a pulse rate of greater than about 10 KHz. In embodiments, an RF source 312 applies RF bias to the substrate of less than or equal to about 500 W at a frequency from about 2 MHz to about 20 MHz.

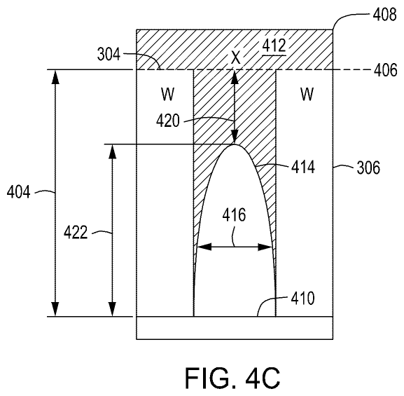

FIG. 4a depicts a structure 400 disposed in the substrate 306 having structure width 402, a structure depth 404 equal to a perpendicular linear distance from a point coplanar with the top surface 304 of the substrate 306 (represented by point (x) on dotted line 406) to a bottom surface 410 of the structure 400. FIG. 4a further depicts a portion of a layer of SiO₂ 408 disposed over a portion of the top surface 304 of the substrate 306, but which does not form a cap 412 over the structure 400 as shown in FIG. 4b, In other words, in FIG. 4a, the layer of SiO₂ 408 disposed over the top surface 304 of the substrate 306 does not completely cover and plug the top of the structure 400.

In some embodiments, the structure 400 disposed in the substrate 306 has a structure width 402 of less than or equal to about 20 nm, or less than or equal to about 15 nm, or less than or equal to about 10 nm, and a structure depth 404 of greater than or equal to about 60 nm, or greater than or equal to about 80 nm, or greater than or equal to about 100 nm. As depicted in FIGS. 4a and 4b, the structure may be disposed within a layer of tungsten.

FIG. 4b depicts the same structure 400 from FIG. 4a, disposed within the substrate 306, wherein a layer of SiO₂ disposed over a top surface 304 of the substrate 306 forms a cap 412 over the structure 400 with an airgap 414 disposed between the cap 412 and the bottom surface 410 of the structure 400. As depicted in FIG. 4b, in embodiments, a maximum width 416 of the airgap 414 formed within the structure 400 is greater than or equal to about 40% of a structure width 402. In some embodiments, the maximum width 416 of the airgap 414 formed within the structure 400 is greater than 90% of the structure width.

FIG. 4b further depicts a distance 420 from a top 418 of the airgap 414 to a point (x) coplanar 406 with the top surface 304 of the substrate 306 is greater than or equal to about 25 nm, which in embodiments may be greater than or equal to about 30 nm, or greater than or equal to about 35 nm, or greater than or equal to about 40 nm.

As is also depicted in FIG. 4b, in embodiments, a length 422 of the airgap 414 is from about 25 nm less than a structure depth 404 to about 45 nm less than the structure depth 404 (see FIG. 4a).

FIG. 4c depicts an embodiment in which the maximum width 416 of the airgap 414 formed within the structure 400 is equal to the structure width 402, a distance from a top 418 of the airgap 414 to a point (x) coplanar 406 with the top surface 304 of the substrate 306 is greater than or equal to about 25 nm, and a length 422 of the airgap 414 is from about 25 nm less than a structure depth to about 45 nm less than the structure depth 404 of the structure 400.

In embodiments, the resulting substrate according to embodiments herein having a structure 400 disposed within the substrate 306 in which a layer of SiO₂ 408 is disposed over a top surface 304 of the substrate 306 forming a cap 412 over the structure 400 with an airgap 414 disposed between the cap 412 and a bottom surface 410 of the structure 400, has a dielectric constant of less than about 2, or less than about 1.8.

In embodiments, the distance from a top 418 of the airgap 414 to a point (x) coplanar 406 with the top surface 304 of the substrate 306 is sufficient such that upon further processing, e.g., CMP, in which all or a portion of the layer of SiO₂ 408 disposed over the top surface 304 of the substrate 306 is removed, the airgap 414 remains beneath the cap 412 covering the opening of the structure 400.

In embodiments, the distance from a top 418 of the airgap 414 to a point (x) coplanar 406 with the top surface 304 of the substrate 306 may be controlled by controlling the voltage and/or the pulse rate at which the target is pulsed, by controlling the RF bias, and/or by controlling the pressure of diatomic oxygen, which is related to the mass:mass ratio of diatomic oxygen to the inert carrier gas. The distance from a top 418 of the airgap 414 to a point (x) coplanar 406 with the top surface 304 of the substrate 306 may be increased by decreasing the voltage and/or increasing the power including the pulse rate at which the target is pulsed, and/or decreasing the RF bias applied to the substrate, and/or by increasing the partial pressure of diatomic oxygen, which is related to increasing the mass:mass ratio of diatomic oxygen to the inert carrier gas.

While the foregoing is directed to embodiments of the present disclosure, other and further embodiments of the disclosure may be devised without departing from the basic scope thereof.

1. A method to form an airgap within a structure of a substrate, comprising:
anisotropically depositing a layer of SiO₂ on a top surface of the substrate to form a cap over the structure and the airgap disposed between the cap and a bottom surface of the structure via reactive negative ion sputtering of a silicon (Si) target in a presence of diatomic oxygen in an inert carrier gas, wherein the target is pulsed at a voltage of less than or equal to about −200 V at a pulse rate of greater than about 10 KHz.

2. The method of claim 1, wherein the target is pulsed at a voltage of about −300 V to about −500 V at a pulse rate from about 10 kHz to about 1000 KHz.

3. The method of claim 1, further comprising applying an RF bias to the substrate of less than or equal to about 500 W.

4. The method of claim 3, wherein the RF bias is applied at a frequency from about 2 MHz to about 20 MHz.

5. The method of claim 1, wherein a weight-to-weight ratio of diatomic oxygen to the inert carrier gas is greater than or equal to about 1:1.

6. The method of claim 5, wherein the inert carrier gas comprises argon, and wherein a weight-to-weight ratio of diatomic oxygen to argon is greater than or equal to about 10:1.

7. The method of claim 1, wherein the substrate is maintained at a temperature from about 200° C. to about 500° C.

8. The method of claim 1, wherein the structure has a structure width of less than or equal to about 20 nm, and a structure depth of greater than or equal to about 60 nm.

9. The method of claim 1, wherein a maximum width of the airgap formed within the structure is greater than or equal to about 40% of a structure width.

10. The method of claim 9, wherein the maximum width of the airgap formed within the structure is greater than 90% of the structure width.

11. The method of claim 1, wherein a distance from a top of the airgap to a point coplanar with the top surface of the substrate is greater than or equal to about 25 nm.

12. The method of claim 11, wherein the distance from the top of the airgap to the point coplanar with the top surface of the structure is from about 30 nm to about 40 nm.

13. The method of claim 1, wherein a length of the airgap is from about 25 nm less than a structure depth to about 45 nm less than the structure depth.

14. The method of claim 1, wherein a first layer of SiO₂ is deposited on the top surface of the substrate at a first deposition rate, followed by depositing a second layer of SiO₂ on the first layer and on the top surface of the substrate at a second deposition rate to form the cap over the structure, wherein the second deposition rate is greater than the first deposition rate.

15. The method of claim 14, wherein the first layer of SiO₂ is deposited while the target is pulsed at a first voltage, and the second layer is deposited while the target is pulsed at a second voltage which is less than the first voltage.

16. The method of claim 14, wherein a first weight-to-weight ratio of diatomic oxygen to the inert carrier gas of the first deposition rate is less than a second weight-to-weight ratio of diatomic oxygen to the inert carrier gas of the second deposition rate.

17. The method of claim 14, wherein an RF bias is applied to the substrate dure the first deposition rate is at a first power, and the RF bias applied to the substrate during the second deposition rate is at a second power which is less than the first power.

18. A substrate, comprising:
a structure disposed within the substrate having a structure width of less than or equal to about 20 nm, and a structure depth of greater than or equal to about 60 nm; and
a layer of SiO₂ disposed over a top surface of the substrate forming a cap over the structure with an airgap disposed between the cap and a bottom surface of the structure;
wherein a distance from a top of the airgap to a point coplanar with a top surface of the substrate is greater than or equal to about 25 nm;
wherein a maximum width of the airgap formed is greater than or equal to about 40% of the structure width; and
wherein a length of the airgap is greater than or equal to about 25 nm less than the structure depth.

19. The substrate of claim 18, wherein:
the distance from the top of the airgap to the point coplanar with the top surface of the substrate is greater than or equal to about 25 nm;
the maximum width of the airgap is greater than or equal to about 90% of the structure width;
a length of the airgap is equal to the distance from a top of the airgap to the bottom surface of the structure; and
the structure has a dielectric constant K of less than about 2.

20. A non-transitory computer readable medium, having instructions stored thereon which, when executed, cause a processing chamber to perform a method to form an airgap within a structure of a substrate, the method comprising:
anisotropically depositing a layer of SiO₂ on a top surface of the substrate to form a cap over the structure and the airgap disposed between the cap and a bottom surface of the structure via reactive negative ion sputtering of a silicon (Si) target in a presence of diatomic oxygen in an inert carrier gas, wherein the target is pulsed at a voltage of less than or equal to about −200 V at a pulse rate of greater than about 10 KHz.
